(19) United States
(12) Patent Application Publication
(10) Pub. No.: US 2019/0198422 A1
(43) Pub. Date: Jun. 27, 2019

(54) SEMICONDUCTOR APPARATUS AND MANUFACTURING METHOD THEREOF

(71) Applicant: Huawei Technologies Co., Ltd., Shenzhen (CN)

(72) Inventors: Jyh Rong LIN, Hsinchu (TW); Wenjun HUANG, Hsinchu (TW)

(21) Appl. No.: 16/287,629

(22) Filed: Feb. 27, 2019

Related U.S. Application Data
(63) Continuation of application No. PCT/CN2017/074449, filed on Feb. 22, 2017.

(30) Foreign Application Priority Data
Aug. 31, 2016 (CN) 201610799678.X

(51) Int. Cl. H01L 23/373; H01L 21/56; H01L 23/00

(52) U.S. Cl. CPC H01L 23/3735; H01L 23/3733; H01L 23/49816; H01L 24/29; H01L 24/32; H01L 21/56

(57) ABSTRACT

The present disclosure discloses a semiconductor apparatus and method of manufacturing. The apparatus includes: a circuit device and a heat sink fin that are disposed in a laminated manner, and a thermal interface material layer located between the circuit device and the heat sink fin. A packaging layer is disposed around a side wall of the circuit device. A first surface of the thermal interface material layer is thermally coupled to the circuit device and the packaging layer, and a second surface is thermally coupled to the heat sink fin. In the foregoing solution, the packaging layer and the circuit device are both thermally coupled to the thermal interface material layer, a contact area between the circuit device and the thermal interface material layer is increased.

### CROSS-REFERENCE TO RELATED APPLICATIONS

This application is a continuation of International Application No. PCT/CN2017/074449, filed on Feb. 22, 2017, which claims priority to Chinese Patent Application No. 201610799678.X, filed on Aug. 31, 2016, the disclosures of the aforementioned applications are hereby incorporated by reference in their entireties.

### TECHNICAL FIELD

The present application relates to the field of semiconductor technologies, and in particular, to a semiconductor apparatus and a manufacturing method thereof.

### BACKGROUND

FIG. 1A is a schematic sectional view of an integrated circuit chip in the prior art and a partial package structure of the integrated circuit chip. The structure includes an integrated circuit chip 1A02, a thermal interface material layer 1A04, and a heat sink 1A06. The thermal interface material layer 1A04 has multiple metal particles 1A08 distributed in a form of a dispersed phase. Heat generated by the integrated circuit chip 1A02 in an operating process is guided into the heat sink 1A06 through the thermal interface material layer 1A04 on a rear side of the chip. However, in the prior art, because a size of the integrated circuit chip 1A02 is limited, a heat transfer effect is relatively undesirable. Consequently, it is very difficult to meet a heat dissipation requirement of a high-power chip.

### SUMMARY

Embodiments of the present disclosure provide a semiconductor apparatus and a manufacturing method thereof. In the semiconductor apparatus, a contact area between a thermal interface material layer and a circuit device is increased by using a disposed packaging layer, so as to greatly improve thermal conductivity effectiveness of an entire heat conduction path, thereby better meeting a heat dissipation requirement of a high-power-consumption circuit device.

According to a first aspect, an embodiment of the present disclosure provides a semiconductor apparatus, including a circuit device and a heat sink fin that are disposed in a laminated manner, and a thermal interface material layer located between the circuit device and the heat sink fin, where
a packaging layer is disposed around a side wall of the circuit device, the circuit device includes an integrated circuit die, the integrated circuit die is provided with a pin, one surface that is of the integrated circuit die and on which the pin is disposed is a mounting surface, and the side wall of the circuit device is a wall that is of the integrated circuit die and that is adjacent to the mounting surface; and
the thermal interface material layer has a first surface facing the circuit device and the packaging layer and a second surface facing the heat sink fin, the first surface is thermally coupled to the circuit device and the packaging layer, and the second surface is thermally coupled to the heat sink fin.

In the foregoing solution, because the packaging layer is disposed around the circuit device, and the packaging layer and the circuit device are both thermally coupled to the thermal interface material layer, a contact area between the circuit device and the thermal interface material layer is increased. In addition, heat generated on the side wall of the circuit device may be transferred to the thermal interface material layer through the packaging layer, and then transferred to the heat sink fin, thereby improving a heat dissipation effect of the semiconductor apparatus. In addition, one packaging layer is disposed around an exterior side of the circuit device, so as to increase a laying area of the thermal interface material layer, increase an area of a contact surface of the thermal interface material layer, reduce an interface stress, and correspondingly improve component reliability.

The packaging layer uses a plastic film layer. The plastic film layer has a desirable heat transfer effect, and can rapidly transfer the heat generated on the side wall of the circuit device to the thermal interface material layer, thereby improving heat dissipation efficiency of the circuit device.

The thermal interface material layer includes: a first alloy layer, thermally coupled to the circuit device and the packaging layer; a nano-metal particle layer, thermally coupled to the first alloy layer, where the nano-metal particle layer includes multiple nano-metal particles that are coupled to each other and an intermediate mixture, and the intermediate mixture is filled between the multiple nano-metal particles; and a second alloy layer, thermally coupled to the nano-metal particle layer and the heat sink fin. The used thermal interface material layer no longer includes high polymer materials with a relatively low thermal conductivity in silver adhesive materials, but includes nano-metal particles instead. The thermal interface material in this embodiment of the present disclosure has a relatively high thermal conductivity, so as to greatly improve thermal conductivity effectiveness of an entire heat conduction path, thereby better meeting a heat dissipation requirement of a high-power chip.

In specific disposition, a sintered continuous phase structure is formed at a contact portion between the first alloy layer and the nano-metal particle layer, sintered continuous phase structures are formed at contact portions between the multiple nano-metal particles, and a sintered continuous phase structure is formed at a contact portion between the second alloy layer and the nano-metal particle layer. A connection effect between the circuit device and the heat sink fin is improved by using the sintered continuous phase structure, and a heat transfer effect between the circuit device and the heat sink fin is improved.

In a specific implementation solution, the nano-metal particles include silver, and have a desirable heat transfer effect. In addition, in specific disposition, diameters of the nano-metal particles are between 50 nanometers and 200 nanometers.

The semiconductor apparatus provided in this embodiment is used for a flip chip ball grid array package structure.

The first alloy layer includes a first adhesive layer and a first co-sintered layer, the first adhesive layer is thermally coupled to the circuit device and the packaging layer, the first co-sintered layer is coupled to the nano-metal particle layer, and a sintered continuous phase structure is formed at a contact portion between the first co-sintered layer and the nano-metal particle layer. By using the foregoing structure, connection strength of thermal coupling of the first alloy layer to the circuit device and the packaging layer is increased, and a desirable heat transfer effect is achieved.

In specific disposition, the first adhesive layer includes any one of the following materials: titanium, chromium, nickel, or a nickel-vanadium alloy, and the first co-sintered layer includes any one of the following materials: silver, gold, or copper. The foregoing materials all have relatively desirable heat transfer effects.

In addition, in a solution, the first alloy layer further includes a first buffer layer, located between the first adhesive layer and the first co-sintered layer, and the first buffer layer includes any one of the following materials: aluminum, copper, nickel, or a nickel-vanadium alloy.

In specific disposition, the second alloy layer includes a second adhesive layer and a second co-sintered layer, the second adhesive layer is thermally coupled to the heat sink fin, the second co-sintered layer is thermally coupled to the nano-metal particle layer, and a sintered continuous phase structure is formed at a contact portion between the second co-sintered layer and the nano-metal particle layer. By using the foregoing structure, connection strength of thermal coupling of the second alloy layer to the heat sink fin is increased, and a desirable heat transfer effect is achieved.

In addition, in specific disposition, the second adhesive layer includes any one of the following materials: titanium, chromium, nickel, or a nickel-vanadium alloy, and the second co-sintered layer includes any one of the following materials: silver, gold, or copper. The foregoing materials all have relatively desirable heat transfer effects.

In a solution, the second alloy layer further includes a second buffer layer, located between the second adhesive layer and the second co-sintered layer, and the second buffer layer includes any one of the following materials: aluminum, copper, nickel, or a nickel-vanadium alloy.

Diameters of the nano-metal particles are not greater than 1 micrometer.

Different materials may be selected for the intermediate mixture. In a specific implementation, the intermediate mixture includes either of the following materials: air or resin.

An embodiment of the present disclosure provides a semiconductor apparatus manufacturing method, including: disposing a packaging layer around a side wall of a circuit device, where the circuit device includes an integrated circuit die, the integrated circuit die is provided with a pin, one surface that is of the integrated circuit die and on which the pin is disposed is a mounting surface, and the side wall of the circuit device is a wall that is of the integrated circuit die and that is adjacent to the mounting surface;
generating a thermal interface material layer, where the thermal interface material layer has a first surface facing the circuit device and the packaging layer and a second surface facing the heat sink fin; and
thermally coupling the first surface to the circuit device and the packaging layer, and thermally coupling the second surface to the heat sink fin.

In the foregoing solution, because the packaging layer is disposed around the circuit device, and the packaging layer and the circuit device are both thermally coupled to the thermal interface material layer, a contact area between the circuit device and the thermal interface material layer is increased. In addition, heat generated on the side wall of the circuit device may be transferred to the thermal interface material layer through the packaging layer, and then transferred to the heat sink fin, thereby improving a heat dissipation effect of the semiconductor apparatus. In addition, one packaging layer is disposed around an exterior side of the circuit device, so as to increase a laying area of the thermal interface material layer, increase an area of a contact surface of the thermal interface material layer, reduce an interface stress, and correspondingly improve component reliability.

During specific fabrication, the generating a thermal interface material layer, where the thermal interface material layer has a first surface facing the circuit device and the packaging layer and a second surface facing the heat sink fin is specifically:
generating a first alloy layer;
generating a nano-metal particle layer by using multiple nano-metal particles that are coupled to each other and an intermediate mixture, and filling the intermediate mixture between the multiple nano-metal particles;
generating a second alloy layer; and
thermally coupling the nano-metal particle layer to the first alloy layer and the second alloy layer separately, where one surface that is of the first alloy layer and that deviates from the nano-metal particle layer is the first surface, and one surface that is of the second alloy layer and that deviates from the nano-metal particle layer is the second surface.

The manufacturing method further includes: forming a sintered continuous phase structure at a contact portion between the first alloy layer and the nano-metal particle layer, forming sintered continuous phase structures at contact portions between the nano-metal particles, and forming a sintered continuous phase structure at a contact portion between the second alloy layer and the nano-metal particle layer.

Diameters of the nano-metal particles are not greater than 1 micrometer.

The intermediate mixture includes either of the following materials: air or resin.

During specific fabrication of the first alloy layer, a first adhesive layer and a first co-sintered layer are generated, the first adhesive layer is thermally coupled to the circuit device and the packaging layer, the first co-sintered layer is coupled to the nano-metal particle layer, and a sintered continuous phase structure is formed at a contact portion between the first co-sintered layer and the nano-metal particle layer.

During specific fabrication of the second alloy layer, a second adhesive layer and a second co-sintered layer are generated, the second adhesive layer is thermally coupled to the heat sink fin, the second co-sintered layer is thermally coupled to the nano-metal particle layer, and a sintered continuous phase structure is formed at a contact portion between the second co-sintered layer and the nano-metal particle layer.

The disposing a packaging layer around a side wall of a circuit device includes: disposing the packaging layer around the side wall by using a plastic film as a material for manufacturing the packaging layer. The plastic film has a desirable heat transfer effect. Heat dissipation efficiency of the circuit device is improved by using the disposed packaging layer that is fabricated from the plastic film.

### BRIEF DESCRIPTION OF DRAWINGS

To describe the technical solutions in the embodiments of the present disclosure or in the prior art more clearly, the following briefly describes the accompanying drawings required for describing the embodiments or the prior art. Apparently, the accompanying drawings in the following description show merely some embodiments of the present disclosure, and a person of ordinary skill in the art may still derive other drawings from these accompanying drawings without creative efforts.

FIG. 1A is a schematic sectional view of a package structure including a semiconductor apparatus in the prior art;

FIG. 1B is a schematic sectional view of a semiconductor apparatus according to a first embodiment of the present disclosure;

FIG. 2 is a schematic diagram of a combination of a circuit device and a packaging layer of the semiconductor apparatus according to the first embodiment of the present disclosure;

FIG. 3 is a schematic sectional view of thermal coupling of a thermal interface material layer to the circuit device and the packaging layer according to the first embodiment;

FIG. 4 is a schematic sectional view of a first embodiment of a first alloy layer in FIG. 3;

FIG. 5 is a schematic sectional view of a second embodiment of the first alloy layer in FIG. 3;

FIG. 6 is a schematic sectional view of a first embodiment of a second alloy layer in FIG. 3;

FIG. 7 is a schematic sectional view of a second embodiment of the second alloy layer in FIG. 3; and

FIG. 8 is a flowchart of a semiconductor apparatus manufacturing method according to a second embodiment of the present disclosure.

### DESCRIPTION OF EMBODIMENTS

The following clearly describes the technical solutions in the embodiments of the present disclosure with reference to the accompanying drawings in the embodiments of the present disclosure. Apparently, the described embodiments are merely some but not all of the embodiments of the present disclosure. All other embodiments obtained by a person of ordinary skill in the art based on the embodiments of the present disclosure without creative efforts shall fall within the protection scope of the present disclosure.

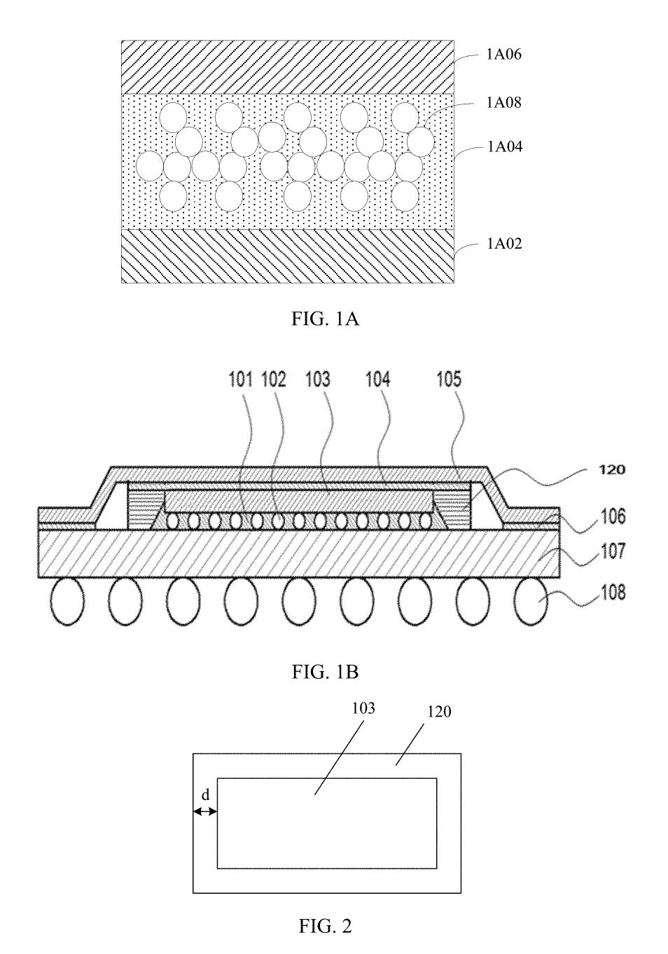

For convenience of description, a side wall of a circuit device is defined in the embodiments. In the embodiments, the side wall of the circuit device is a wall that is of the circuit device and that is adjacent to one surface (a mounting surface) on which a pin is disposed. In FIG. 1B, FIG. 1B is a schematic sectional view of a semiconductor apparatus according to a first embodiment of the present disclosure. Using a placement direction of the semiconductor apparatus as a reference direction, a side wall of the circuit device is one surface in a vertical direction shown in FIG. 1B.

An embodiment of the present disclosure provides a semiconductor apparatus. The semiconductor apparatus includes: a circuit device and a heat sink fin 105 that are disposed in a laminated manner, and a thermal interface material layer 104 located between the circuit device and the heat sink fin 105, where
a packaging layer 120 is disposed around a side wall of the circuit device, the circuit device includes an integrated circuit die 103, the integrated circuit die 103 is provided with a pin, one surface that is of the integrated circuit die 103 and on which the pin is disposed is a mounting surface, and the side wall of the circuit device is a wall that is of the integrated circuit die 103 and that is adjacent to the mounting surface; and
the thermal interface material layer 104 has a first surface facing the circuit device and the packaging layer 120 and a second surface facing the heat sink fin 105, the first surface is thermally coupled to the circuit device and the packaging layer 120, and the second surface is thermally coupled to the heat sink fin 105.

Referring to FIG. 1B and FIG. 2 together, FIG. 1B is a schematic sectional view of the semiconductor apparatus according to the first embodiment of the present disclosure. FIG. 2 is a top view of a combination of the circuit device and the packaging layer in this embodiment. FIG. 2 is a schematic structural diagram of the circuit device (the integrated circuit die 103) and the packaging layer 120 that are seen from top to bottom by using a placement direction of the device shown in FIG. 1B as a reference direction. In FIG. 2, the circuit device has a regular rectangular shape. It should be understood that, FIG. 2 shows only a positional relationship between the circuit device and the packaging layer 120. A shape of the circuit device is not limited to the rectangular shape in FIG. 2, and may be any other shape. With reference to FIG. 1B and FIG. 2, it may be known that, the packaging layer 120 provided in this embodiment is disposed around the side wall of the circuit device. That is, the packaging layer 120 may be considered as a structure that is formed by surrounding the circuit device and that envelops the side wall of the circuit device. That is, as shown in FIG. 1B, when the circuit device includes the integrated circuit die 103 and a bottom filler 101, the packaging layer 120 envelops a side wall of the integrated circuit die 103 and a side wall of the bottom filler 101. In addition, a top surface of the packaging layer 120 (one surface that is of the packaging layer and that can be seen in FIG. 2) is flush with a top surface of the integrated circuit die 103 (one surface that is of the integrated circuit die 103 and that can be seen in FIG. 2). The top surface of the packaging layer 120 and the top surface of the integrated circuit die 103 together form a contact surface that is connected to the thermal interface material layer 104. The heat sink fin 105 is fastened on a substrate 107 by using an adhesive 106, and the pin of the integrated circuit die 103 is connected to a circuit of the substrate 107. The thermal interface material layer 104 is thermally coupled to the integrated circuit die 103 and the heat sink fin 105. In specific disposition, the thermal interface material layer 104 covers the top surfaces (surfaces shown in FIG. 2) of the integrated circuit die 103 and the packaging layer 120, and is thermally coupled to the top surfaces. Because the packaging layer 120 has a particular thickness d (that is, a width of a frame-shaped surface), the packaging layer 120 forms a frame-shaped contact surface (as shown in FIG. 2) that is thermally coupled to the thermal interface material layer 104. In addition, in specific disposition, the packaging layer 120 has the specified thickness d to ensure that the packaging layer 120 can completely package the circuit device. Therefore, a frame of the frame-shaped contact surface has a particular width (the width is equal to the thickness of the packaging layer 120). Specifically, when there is no packaging layer 120, a coupling area is only an area of the top surface of the integrated circuit die 103. After the packaging layer 120 is added, as shown in FIG. 2, the coupling area is a sum of the area of the top surface of the integrated circuit die 103 and an area of the top surface of the packaging layer 120, so that an area of a thermal coupling surface between the thermal interface material layer 104 and the integrated circuit die 103 is increased. In addition, the coupling area is increased, so that connection strength between the thermal interface material layer 104 and the integrated circuit die 103 is increased, and an interface stress is reduced (an entire stress stays unchanged, but a contact area is increased, so that stress impact on per unit of area is reduced), thereby improving component reliability performance.

In addition, in specific disposition, the packaging layer 120 is attached on the side wall of the circuit device. Therefore, during heat dissipation, heat on the side wall of the circuit device is transferred to the thermal interface material layer 104 through the packaging layer 120, and is further dissipated to the heat sink fin 105. By using the foregoing structure, it may be known that a heat dissipation manner of the circuit device is dissipating heat on a top surface of the circuit device along a path from the thermal interface material layer 104 to the heat sink fin 105 and dissipating the heat on the side wall of the circuit device along a path from the packaging layer 120 through the thermal interface material layer 104 to the heat sink fin 105, so as to increase a heat dissipation area of the circuit device, thereby improving a heat dissipation effect of the circuit device.

In a specific implementation, the packaging layer 120 uses a plastic film layer. The plastic film layer has a desirable packaging effect and a desirable heat transfer effect, so that the plastic film layer can rapidly transfer heat to the thermal interface material layer, thereby improving the heat dissipation effect of the circuit device.

As shown in FIG. 1B and FIG. 2, when a flip chip ball grid array package structure is used, the entire semiconductor apparatus includes a solder ball 108, the substrate 107, the adhesive 106, a metal bump (BUMP) 102, the circuit device (for example, the integrated circuit die 103), the packaging layer 120 (for example, the plastic film layer) disposed around the circuit device 103, the thermal interface material layer 104, and the heat sink fin 105. The integrated circuit die 103 is coupled to the substrate 107 by using the metal bump 102. The metal bump 102 is protected by the bottom filler 101, and the packaging layer 120 is disposed around the integrated circuit die 103. In addition, in specific disposition, in this embodiment, thermal coupling includes a case in which there is heat transfer between different layers, different structures, or different apparatuses. More specifically, the thermal interface material layer 104 may be located between the integrated circuit die 103 and the heat sink fin 105. In addition, a substrate in the integrated circuit die 103 is thermally coupled to the thermal interface material layer 104, and the packaging layer is also thermally coupled to the thermal interface material layer 104. Heat of the integrated circuit die 103 reaches the heat sink fin 105 through the thermal interface material layer 104.

The integrated circuit die 103, the packaging layer 120 disposed around the circuit device 103, the thermal interface material layer 104, and the heat sink fin 105 may be some or all of components of a semiconductor apparatus. The semiconductor apparatus may be used for the flip chip ball grid array package structure shown in the figure, but no limitation is set thereto.

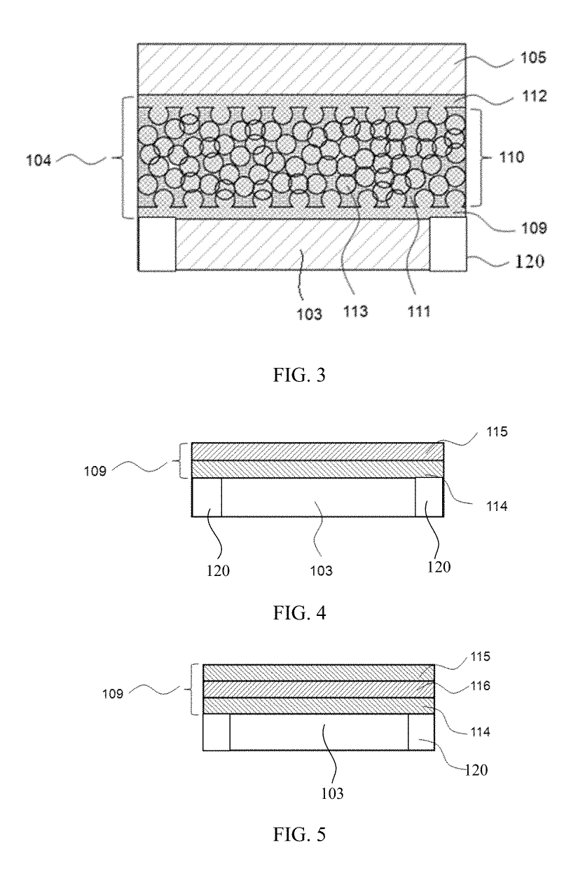

FIG. 3 is a schematic sectional view of thermal coupling of the thermal interface material layer to the circuit device and the packaging layer according to the first embodiment. FIG. 3 shows only an upper half structure of the integrated circuit die 103 that are connected to the thermal interface material layer 104 being connected in FIG. 1B. For the packaging layer 120, also only an upper half structure of the packaging layer 120 is shown. The upper half structure does not include the bottom filler 101. The thermal interface material layer 104 is thermally coupled to the integrated circuit die 103, the packaging layer 120, and the heat sink fin 105, and includes a first alloy layer 109, a nano-metal particle layer 110, and a second alloy layer 112.

The nano-metal particle layer 110 is thermally coupled to the integrated circuit die 103 and the packaging layer 120 by using the first alloy layer 109. More specifically, as shown in FIG. 3, the first alloy layer 109 may be located on the integrated circuit die 103 and the packaging layer 120 and under the nano-metal particle layer 110. That is, the first alloy layer 109 may be located between the integrated circuit die 103 and the nano-metal particle layer 110. The first alloy layer 109 increases adhesive strength between the integrated circuit die 103 and the nano-metal particle layer 110, and a coverage area of the first alloy layer 109 is increased by disposing the packaging layer 120. That is, an area of the formed first alloy layer 109 is increased, thereby increasing an area of the formed thermal interface material layer 104.

The nano-metal particle layer 110 includes nano-metal particles and an intermediate mixture. The intermediate mixture includes, but is not limited to, either of the following materials: air or resin. The intermediate mixture is filled between multiple nano-metal particles, to make the multiple nano-metal particles form a whole. The nano-metal particles include, but are not limited to, silver. Diameters of the nano-metal particles are not greater than 1 micrometer. In an embodiment, the diameters of the nano-metal particles are between 50 nanometers and 200 nanometers. The nano-metal particle layer 110 has a relatively low thermal resistance, and forms a relatively desirable heat conduction path.

The second alloy layer 112 is thermally coupled to the nano-metal particle layer 110 and the heat sink fin 105. More specifically, as shown in the figure, the second alloy layer 112 may be located on the nano-metal particle layer 110 and under the heat sink fin 105. That is, the second alloy layer 112 may be located between the nano-metal particle layer 110 and the heat sink fin 105. The second alloy layer 112 increases adhesive strength between the nano-metal particle layer 110 and the heat sink fin 105.

In an embodiment, a sintered continuous phase structure is formed at a contact portion between the first alloy layer 109 and the nano-metal particle layer 110, sintered continuous phase structures are formed at contact portions between the nano-metal particles, and a sintered continuous phase structure is formed at a contact portion between the second alloy layer 112 and the nano-metal particle layer 110. The sintered continuous phase structure in this specification includes, but is not limited to, a whole structure formed of metal particles as metal atoms near contact portions of the metal particles spread to metal particle interfaces and fuse with the metal particle interfaces because the metal particles are sintered.

FIG. 4 is a schematic sectional view of a first embodiment of the first alloy layer 109 in FIG. 3. FIG. 4 also shows only an upper half structure of the packaging layer 120 and the integrated circuit die 103. As shown in the figure, the first alloy layer 109 includes a first adhesive layer 114 and a first co-sintered layer 115. A co-sintered layer in this specification includes, but is not limited to, a metal layer that is generated in a packaging process and that fuses with a thermal interface material layer, and the metal layer and particles in the thermal interface material layer are co-sintered to form a heat flux path. The first adhesive layer 114 is thermally coupled to the integrated circuit die 103 and the packaging layer 120. The first co-sintered layer 115 is thermally coupled to the nano-metal particle layer 110. A sintered continuous phase structure is formed at a contact portion between the first co-sintered layer 115 and the nano-metal particle layer 110. Specifically, the first adhesive layer 114 may be located on the integrated circuit die 103 and the packaging layer 120, and the first co-sintered layer 115 may be located on the first adhesive layer 114 and under the nano-metal particle layer 110. The first adhesive layer 114 includes, but is not limited to, any one of the following materials: titanium, chromium, nickel, or nickel/vanadium. The first adhesive layer 114 increases bonding strength between the integrated circuit die 103 and the first co-sintered layer 115. The first co-sintered layer 115 includes, but is not limited to, any one of the following materials: silver, gold, or copper.

FIG. 5 is a schematic sectional view of a second embodiment of the first alloy layer 109 in FIG. 3. FIG. 5 also shows only an upper half structure of the packaging layer 120 and the integrated circuit die 103. Compared with FIG. 3, the first alloy layer 109 in FIG. 4 further includes a first buffer layer 116 located between the first adhesive layer 114 and the first co-sintered layer 115. The first buffer layer 116 includes, but is not limited to, any one of the following materials: aluminum, copper, or nickel. The first buffer layer 116 provides a stress buffering function during deformation caused by heat processing, and reduces a risk of a crack that appears between the integrated circuit die 103 and the thermal interface material layer 114 or in the middle of the thermal interface material layer 114, thereby increasing reliability of the semiconductor apparatus.

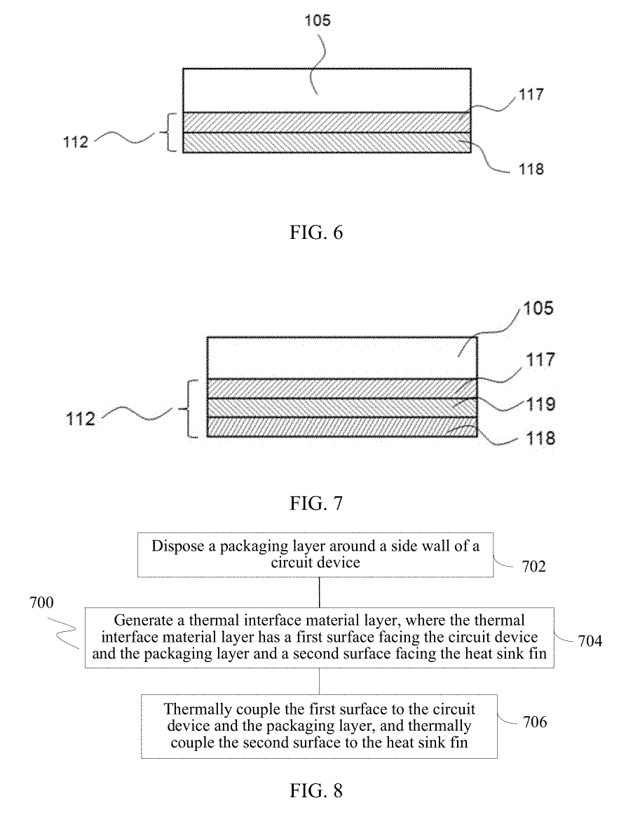

FIG. 6 is a schematic sectional view of a first embodiment of the second alloy layer 112 in FIG. 3. As shown in the figure, the second alloy layer 112 includes a second co-sintered layer 118 and a second adhesive layer 117. The second co-sintered layer 118 is thermally coupled to the nano-metal particle layer 110. A sintered continuous phase structure is formed at a contact portion between the second co-sintered layer 118 and the nano-metal particle layer 110. The second adhesive layer 117 is thermally coupled to the heat sink fin 105. Specifically, the second co-sintered layer 118 may be located on the nano-metal particle layer 110, and the second adhesive layer 117 may be located on the second co-sintered layer 118 and under the heat sink fin 105. The second co-sintered layer 118 includes, but is not limited to, any one of the following materials: silver, gold, or copper. The second adhesive layer 117 includes, but is not limited to, any one of the following materials: titanium, chromium, nickel, or nickel/vanadium. The second adhesive layer 117 increases bonding strength between the second co-sintered layer 115 and the heat sink fin 105.

FIG. 7 is a schematic sectional view of a second embodiment of the second alloy layer 112 in FIG. 3. Compared with FIG. 6, the second alloy layer 112 in FIG. 7 further includes a second buffer layer 119 located between the second adhesive layer 117 and the second co-sintered layer 118. The second buffer layer 119 includes, but is not limited to, any one of the following materials: aluminum, copper, nickel, or nickel/vanadium. The second buffer layer 119 provides a buffering function during deformation caused by heat processing, and reduces a risk of a crack that appears between the thermal interface material layer and the heat sink fin 105 or in the middle of the thermal interface material layer 114, thereby increasing reliability of the apparatus.

In conclusion, because the thermal interface material layer in this embodiment of the present disclosure no longer includes high polymer materials with a relatively low thermal conductivity in silver adhesive materials, but includes nano-metal particles instead. The thermal interface material in this embodiment of the present disclosure has a relatively high thermal conductivity, so as to greatly improve thermal conductivity effectiveness of an entire heat conduction path, thereby better meeting a heat dissipation requirement of a high-power chip. In addition, one packaging layer 120 is disposed around an exterior side of the integrated circuit die 103, so as to increase a laying area of the thermal interface material layer, increase an area of a contact surface of the thermal interface material layer, reduce an interface stress, and correspondingly improve component reliability.

FIG. 8 is a flowchart 700 of a semiconductor apparatus manufacturing method according to a second embodiment of the present disclosure. As shown in the figure, in step 702, a packaging layer is disposed around a side wall of a circuit device. The circuit device includes an integrated circuit die. The integrated circuit die is provided with a pin, and one surface that is of the integrated circuit die and on which the pin is disposed is a mounting surface. The side wall of the circuit device is a wall that is of the integrated circuit die and that is adjacent to the mounting surface. In step 704, a thermal interface material layer is generated. The thermal interface material layer has a first surface facing the circuit device and the packaging layer and a second surface facing the heat sink fin. In step 706, the first surface is thermally coupled to the circuit device and the packaging layer, and the second surface is thermally coupled to the heat sink fin.

In addition, the disposing a packaging layer around a side wall of a circuit device includes: disposing the packaging layer around the side wall by using a plastic film as a material for manufacturing the packaging layer. The plastic film layer has a desirable heat transfer effect, and can rapidly transfer heat generated on the side wall of the circuit device to the thermal interface material layer, thereby improving heat dissipation efficiency of the circuit device.

During specific manufacturing, the thermal interface material layer is generated. The thermal interface material layer has the first surface facing the circuit device and the packaging layer and the second surface facing the heat sink fin.

A first alloy layer is generated. A nano-metal particle layer is generated by using nano-metal particles that are coupled to each other and an intermediate mixture. Diameters of the nano-metal particles are not greater than 1 micrometer. For example, the diameters of the nano-metal particles are between 50 nanometers and 200 nanometers. The intermediate mixture includes, but is not limited to, either of the following materials: air or resin. In an embodiment, the nano-metal particles include, but are not limited to, silver. A second alloy layer is generated. The nano-metal particle layer is thermally coupled to the circuit device and the packaging layer by using the first alloy layer. The second alloy layer is thermally coupled to the nano-metal particle layer and the heat sink fin.

In an embodiment, the method further includes: forming a sintered continuous phase structure at a contact portion between the first alloy layer and the nano-metal particle layer, forming sintered continuous phase structures at contact portions between the nano-metal particles, and forming a sintered continuous phase structure at a contact portion between the second alloy layer and the nano-metal particle layer.

In an embodiment, the method may be used for a flip chip ball grid array package structure, but no limitation is set thereto.

In an embodiment, the generating a first alloy layer includes: generating a first adhesive layer and a first co-sintered layer, thermally coupling the first adhesive layer to the circuit device and the packaging layer, coupling the first co-sintered layer to the nano-metal particle layer, and forming a sintered continuous phase structure at a contact portion between the first co-sintered layer and the nano-metal particle layer. The first adhesive layer includes, but is not limited to, any one of the following materials: titanium, chromium, nickel, or nickel/vanadium. The first co-sintered layer includes, but is not limited to, any one of the following materials: silver, gold, or copper. In another embodiment, the generating a first alloy layer further includes: generating a first buffer layer between the first adhesive layer and the first co-sintered layer. The first buffer layer includes, but is not limited to, any one of the following materials: aluminum, copper, nickel, or nickel/vanadium.

In an embodiment, the generating a second alloy layer includes: generating a second adhesive layer and a second co-sintered layer, thermally coupling the second adhesive layer to the heat sink fin, thermally coupling the second co-sintered layer to the nano-metal particle layer, and forming a sintered continuous phase structure at a contact portion between the second co-sintered layer and the nano-metal particle layer. The second adhesive layer includes, but is not limited to, any one of the following materials: titanium, chromium, nickel, or nickel/vanadium. The second co-sintered layer includes, but is not limited to, any one of the following materials: silver, gold, or copper. In another embodiment, the generating a second alloy layer further includes: generating a second buffer layer between the second adhesive layer and the second co-sintered layer. The second buffer layer includes, but is not limited to, any one of the following materials: aluminum, copper, nickel, or nickel/vanadium.

The circuit device may include the integrated circuit die. Thermally coupling the first alloy layer to the circuit device and the packaging layer includes thermally coupling the first alloy layer to a substrate in the integrated circuit die and the packaging layer.

The foregoing disclosed above is merely examples of embodiments of the present disclosure, and certainly is not intended to limit the protection scope of the present disclosure. Therefore, equivalent variations made in accordance with the claims of the present disclosure shall fall within the scope of the present disclosure.

What is claimed is:

1. A semiconductor apparatus, comprising:
a circuit device and a heat sink that are disposed in a laminated manner;
a thermal interface material layer located between the circuit device and the heat sink;
a packaging layer disposed around a side wall of the circuit device, wherein the circuit device comprises an integrated circuit die having a pin disposed on a mounting surface of the integrated circuit die, and the side wall of the circuit device is a wall of the integrated circuit die and is adjacent to the mounting surface; and
wherein the thermal interface material layer has a first surface facing the circuit device and the packaging layer and a second surface facing the heat sink, the first surface is thermally coupled to the circuit device and the packaging layer, and the second surface is thermally coupled to the heat sink.

2. The semiconductor apparatus according to claim 1, wherein the packaging layer is a plastic film layer.

3. The semiconductor apparatus according to claim 1, wherein the thermal interface material layer comprises:
a first alloy layer thermally coupled to the circuit device and the packaging layer;
a nano-metal particle layer thermally coupled to the first alloy layer and comprising multiple nano-metal particles coupled to each other and an intermediate mixture, and wherein the intermediate mixture is filled between the multiple nano-metal particles; and
a second alloy layer thermally coupled to the nano-metal particle layer and the heat sink.

4. The semiconductor apparatus according to claim 3, further comprising:
a first sintered continuous phase structure formed at a contact portion between the first alloy layer and the nano-metal particle layer;
multiple sintered continuous phase structures formed at contact portions between the multiple nano-metal particles; and
a second sintered continuous phase structure is formed at a contact portion between the second alloy layer and the nano-metal particle layer.

5. The semiconductor apparatus according to claim 1, wherein the semiconductor apparatus is used in a flip chip ball grid array package structure.

6. The semiconductor apparatus according to claim 3, wherein the first alloy layer comprises a first adhesive layer and a first co-sintered layer, the first adhesive layer is thermally coupled to the circuit device and the packaging layer, the first co-sintered layer is coupled to the nano-metal particle layer, and a sintered continuous phase structure is formed at a contact portion between the first co-sintered layer and the nano-metal particle layer.

7. The semiconductor apparatus according to claim 6, wherein:
the first adhesive layer comprises at least one of the following materials: titanium, chromium, nickel or a nickel-vanadium alloy; and
the first co-sintered layer comprises at least one of the following materials: silver, gold or copper.

8. The semiconductor apparatus according to claim 6, wherein the first alloy layer further comprises a first buffer layer located between the first adhesive layer and the first co-sintered layer, and wherein the first buffer layer comprises at least one of the following materials: aluminum, copper, nickel, or a nickel-vanadium alloy.

9. The semiconductor apparatus according to claim 3, wherein the second alloy layer comprises a second adhesive layer and a second co-sintered layer, the second adhesive layer is thermally coupled to the heat sink, the second co-sintered layer is thermally coupled to the nano-metal particle layer, and a sintered continuous phase structure is formed at a contact portion between the second co-sintered layer and the nano-metal particle layer.

10. The semiconductor apparatus according to claim 9, wherein the second alloy layer further comprises a second buffer layer located between the second adhesive layer and the second co-sintered layer, and the second buffer layer comprises at least one of the following materials: aluminum, copper, nickel, or a nickel-vanadium alloy.

11. The semiconductor apparatus according to claim 3, wherein the intermediate mixture comprises: air or resin.

12. A semiconductor apparatus manufacturing method, comprising:
disposing a packaging layer around a side wall of a circuit device, wherein the circuit device comprises an integrated circuit die having a pin disposed on a mounting surface of the integrated circuit die, and the side wall of the circuit device is a wall of the integrated circuit die and is adjacent to the mounting surface;
generating a thermal interface material layer having a first surface facing the circuit device and facing a packaging layer and having a second surface facing a heat sink; and
thermally coupling the first surface to the circuit device and the packaging layer, and thermally coupling the second surface to the heat sink.

13. The manufacturing method according to claim 12, wherein generating a thermal interface material layer having a first surface facing the circuit device and facing the packaging layer and having a second surface facing the heat sink comprises:
generating a first alloy layer;
generating a nano-metal particle layer comprising multiple nano-metal particles that are coupled to each other and an intermediate mixture, and filling the intermediate mixture between the multiple nano-metal particles;
generating a second alloy layer; and
thermally coupling the nano-metal particle layer to the first alloy layer and the second alloy layer separately, wherein one surface of the first alloy layer that deviates from the nano-metal particle layer is a first surface, and wherein one surface of the second alloy layer that deviates from the nano-metal particle layer is a second surface.

14. The manufacturing method according to claim 13, further comprising:
forming a first sintered continuous phase structure at a contact portion between the first alloy layer and the nano-metal particle layer;
forming multiple sintered continuous phase structures at contact portions between the nano-metal particles; and
forming a second sintered continuous phase structure at a contact portion between the second alloy layer and the nano-metal particle layer.

15. The manufacturing method according to claim 13, wherein generating a first alloy layer comprises:
generating a first adhesive layer and a first co-sintered layer;
thermally coupling the first adhesive layer to the circuit device and the packaging layer;
coupling the first co-sintered layer to the nano-metal particle layer; and
forming a sintered continuous phase structure at a contact portion between the first co-sintered layer and the nano-metal particle layer.

16. The manufacturing method according to claim 13, wherein generating a second alloy layer comprises:
generating a second adhesive layer and a second co-sintered layer;
thermally coupling the second adhesive layer to the heat sink;
thermally coupling the second co-sintered layer to the nano-metal particle layer; and
forming a sintered continuous phase structure at a contact portion between the second co-sintered layer and the nano-metal particle layer.

17. The manufacturing method according to claim 12, wherein disposing a packaging layer around a side wall of a circuit device comprises:
disposing the packaging layer around the side wall using a plastic film as a material for the packaging layer.
